(19) United States
(12) Patent Application Publication
(10) Pub. No.: US 2014/0216332 A1
(43) Pub. Date: Aug. 7, 2014

(54) VACUUM TREATMENT DEVICE

(71) Applicant: ULVAC, INC., Chigasaki-shi (JP)

(72) Inventors: Miki OMORI, Chigasaki-shi (JP); Harunori IWAI, Chigasaki-shi (JP); Yuichi TACHINO, Chigasaki-shi (JP); Masashi KUBO, Chigasaki-shi (JP)

(73) Assignee: ULVAC, INC., Chigasaki-shi (JP)

(21) Appl. No.: 14/252,119

(22) Filed: Apr. 14, 2014

Related U.S. Application Data
(63) Continuation of application No. PCT/JP2012/076063, filed on Oct. 9, 2012.

(30) Foreign Application Priority Data
Oct. 13, 2011 (JP) 2011-225881

(51) Int. Cl. H01L 21/687

(52) U.S. Cl. CPC H01L 21/68742
USPC 118/50

(57) ABSTRACT

Provided is a vacuum treatment device, when a lifting pin inserted to a through hole is moved up, a substrate on a placement table is placed on a lid member which is connected to an upper end of a lifting pin and is separated from a placement surface of the placement table. Additionally, when the lifting pin is moved down, the substrate comes into contact with the placement surface so as to be placed thereon. An annular seal member surrounding a periphery of an opening of the through hole is provided in a portion which faces the lid member in a bottom surface of a depression provided in the placement surface of the placement table. The lid member annularly comes into contact with the seal member when the lifting pin is moved down, and a space inside the through hole and a space outside the through hole are separate by the seal member, thereby preventing gas from flowing into the through hole.

This application is a continuation of International Application No. PCT/JP2012/76063, filed on Oct. 9, 2012, which claims priority to Japan Patent Application No. 2011-225881, filed on Oct. 13, 2011. The contents of the prior applications are herein incorporated by references in their entireties.

### BACKGROUND

The present invention generally relates to a vacuum treatment device.

FIG. 7 shows an internal structure view of a conventional vacuum treatment device 100.

The vacuum treatment device 100 has a vacuum chamber 111. A placement table 121 is arranged inside the vacuum chamber 111; and a lifting pin 127 is inserted into a through hole 124, which is provided in the placement table 121.

In the case where a lifting device 128 is actuated to move up the lifting pin 127, a substrate 131 on the placement table 121 is placed on an upper end of the lifting pin 127, and is separated from a placement surface of the placement table 121. In the case where the lifting pin 127 is moved down, the substrate 131 on the lifting pin 127 moves down so as to come into contact with the placement surface of the placement table 121, and is placed on the placement surface. Reference numeral 117 denotes a heater which heats up the substrate 131 on the placement table 121.

When gas is discharged into the vacuum chamber 111 from a gas discharge device 114 while vacuum evacuating an inside of the vacuum chamber 111 by a vacuum evacuation device 115, a part of the discharged gas flows into an inside of the through hole 124 through a gap between a back surface of the substrate 131 and the placement surface of the placement table 121.

As a result, a gas flow is disturbed in the periphery of the through hole 124 in the placement surface of the placement table 121, and a problem occurs whereby the thickness of a film formed on a surface of the substrate 131 becomes smaller.

Further, there has been a problem whereby the gas flowing into the inside of the through hole 124 adheres to an inner wall surface of the through hole 124 so as to form a particle source, for example, see JPA 2001-199791.

The present invention is made for the purpose of solving the disadvantage in the conventional art mentioned above, and an object of the present invention is to provide a vacuum treatment device which can prevent gas from flowing into a through hole of a placement table to which a lifting pin is inserted.

In order to achieve the above-mentioned object, the present invention provides a vacuum treatment device that includes a vacuum chamber, a placement table which is directed upward and arranged in the vacuum chamber and having a table placement surface where a substrate is placed, a depression provided in the table placement surface, a through hole provided in the placement table and having an opening which is exposed on an internal surface of the depression, a lifting pin inserted to the through hole and has an upper end connected to a lid member, a lifting device which lifts and moves the lifting pin, the lid member being provided on the upper end of the lifting pin and being able to be lifted and moved between a position inside the depression and a position above the depression by a lifting movement of the lifting pin by the lifting device and an annular shaped seal member provided on the internal surface of the depression so as to annularly surround the opening. The lid member comes down by a downward movement of the lifting pin, and a back surface of the lid member and the internal surface of the depression come into contact with the seal member, whereby the seal member is pressed and deformed, and the lid member is arranged inside the depression in a state such that a portion where the lid member and the seal member are in contact, and a portion where the internal surface of the depression and the seal member are in contact annularly surround the opening.

The present invention is the vacuum treatment device which further includes an elastic member, and the elastic member is deformed in a case where the seal member is pressed; and the seal member is pressed by a force restoring the deformation of the elastic member.

The present invention is the vacuum treatment device, wherein a back surface of the lid member annularly comes into contact with the internal surface of the depression above a position where the depression and the lid member come into contact with the seal member.

The present invention is the vacuum treatment device which further includes a bottom surface which is a portion annularly surrounding the opening, in the internal surface of the depression, wherein the seal member is arranged in the bottom surface, and the seal member comes into contact with the back surface of the lid member.

The present invention is the vacuum treatment device further includes a buffer member, wherein the lid member is moved upward by the lifting pin via the buffer member when the lifting pin moves up.

The present invention is the vacuum treatment device, wherein the elastic member is compressed when the lifting pin is moved down.

The present invention is the vacuum treatment device, wherein the elastic member is elongated when the lifting pin is moved down.

The present invention is the vacuum treatment device, wherein a side surface of the depression is inclined upward.

The present in invention is the vacuum treatment device according to claim 1, wherein a material of the lid member is identical to a material of the placement table.

Due to a space inside the seal member being separated from a space outside the seal member by the contact of the lid member with the seal member, gas outside the seal member does not flow into an inside of the through hole inside the seal member, the inside of the through hole is kept clean, and any generation of particle is prevented.

Due to the gas not flowing into the inside of the through hole when used in the case of a film forming process (for example, ALD) in which the gas flow is important, it is possible to prevent the gas flow from being disturbed at the periphery of the through hole, and it is possible to improve a film thickness distribution of the film formed on the substrate on the placement table.

### BRIEF DESCRIPTION OF THE DRAWINGS

FIG. 1 is an internal structure view of a vacuum treatment device according to the present invention.

FIG. 2 is an enlarged view of a portion indicated by reference sign A in FIG. 1.

FIG. 3 is a view for explaining a state in which an elastic member is compressed and a lid member is pressed against a seal member.

FIG. 4 is a view for explaining a state in which a substrate is placed on the lid member and is separated from a placement surface of a placement table.

FIG. 5 is a view for explaining another example of a structural arrangement of the elastic member.

FIG. 6 is a cross sectional view taken along reference line B-B in the placement table shown in FIG. 1.

FIG. 7 is an internal structure view of a conventional vacuum treatment device.

### DETAILED DESCRIPTION OF THE INVENTION

### <Structure of Vacuum Treatment Device>

A description will be given of an example of a structure of a vacuum treatment device according to the present invention.

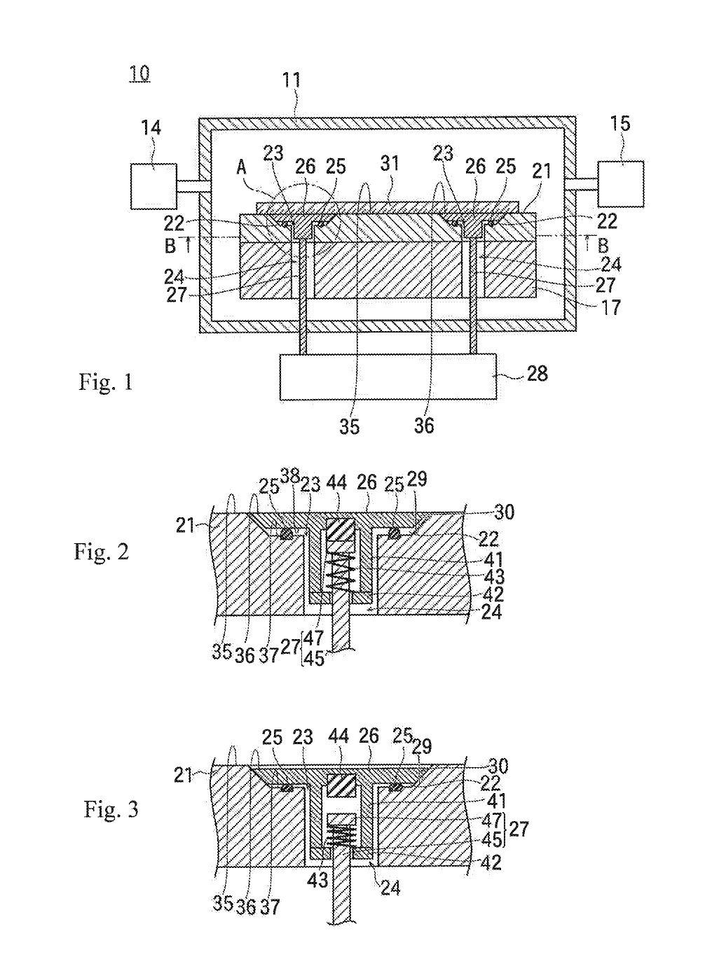

FIG. 1 is an internal structure view of a vacuum treatment device 10.

The vacuum treatment device 10 has a vacuum chamber 11 and a placement table 21.

The placement table 21 has a table placement surface 35 which can accommodate thereon a substrate; and here, the table placement surface 35 is set horizontally and is structured so as to be positioned inside the vacuum chamber 11 while being directed upward. One or a plurality of depressions 22 is formed as a concave portion in the table placement surface 35.

The same number of through holes 24 as the number of the depressions 22 are formed at a position of the table placement surface 35 of the placement table 21; and an opening 23, which is an upper end of one through hole 24, is positioned in an internal surface of each of the depressions 22. Here, each of the through holes 24 is vertically arranged.

In a state shown in FIG. 1, a lid member 26 is arranged inside each of the depressions 22. Because the depressions 22 and the lid members 26 are respectively constructed by the same members, a description will only be given below for one depression 22 and one lid member 26.

A lifting pin 27 is arranged inside the through hole 24 with its lower portion attached to a lifting device 28, and is structured to be able to be moved up and down. When the lifting pin 27 is moved up, an upper end of the lifting pin 27 comes into contact with a bottom surface of the lid member 26, and the lid member 26 is lifted up so as to be moved to an upper portion above the depression 22 from inside the depression 22.

Reference numeral 31 in FIG. 1 denotes a substrate, and the substrate 31 is arranged on the table placement surface 35. When the lid member 26 is lifted up, the substrate 31 is also lifted up together with the lid member 26.

Here, a material of the placement table 21 is aluminum, and a material of the lifting pin 27 is stainless steel.

The lifting device 28 is constructed by a motor, and is connected to a lower end of the lifting pin 27, and is structured so as to transmit power to the lifting pin 27 and move up and down the lifting pin 27.

FIG. 6 is a cross sectional view taken along reference line B-B in the placement table 21 shown in FIG. 1. A gap is provided between an outer peripheral side surface of the lifting pin 27 and an inner peripheral side surface of the through hole 24. With reference to FIG. 1, when the lifting pin 27 moves up and down, the outer peripheral side surface of the lifting pin 27 and the inner peripheral side surface of the through hole 24 do not rub, and no dust is generated.

FIG. 2 is an enlarged view of a portion indicated by reference sign A in FIG. 1.

In the present embodiment, the depression 22 of the placement table 21 has a planar bottom surface 37, and the opening 23 of the through hole 24 is exposed to the center of a bottom surface of the depression 22.

In an external surface of the lid member 26, a lid portion placement surface 36 directed upward and a contact surface 38 forming a surface on an opposite side of the lid portion placement surface 36 are formed as a planar shape, and are set to be parallel to the table placement surface 35, and a tube portion 41 having a cylindrical shape is provided in a portion facing the through hole 24 in the contact surface 38 so as to protrude toward a downward side of the contact surface 38.

A size of the tube portion 41 in a horizontal direction is made larger than a size of the through hole 24 in a horizontal direction; and the tube portion 41 is inserted to an inside of the through hole 24 from the opening 23 in a state such that the lid member 26 is arranged inside the depression 22.

The tube portion 41 is hollow in its inner portion, and a small hole having a smaller diameter than the lifting pin 27 is formed in a bottom surface thereof.

The lifting pin 27 has a shaft portion 45, and a swelling portion 47. The lifting pin 27 is structured such that its shaft portion 45 is inserted to a small hole; and an upper end of the shaft portion 45 is positioned in an internal hollow portion of the tube portion 41. Reference numeral 42 denotes an edge portion which is a peripheral portion of the small hole in the bottom surface of the tube portion 41.

An elastic member 43 constructed by a circularly wound spiral spring is arranged in the hollow portion of the tube portion 41. Here, a diameter of the spring is larger than a diameter of the small hole, and the spring is put on the edge portion 42 in a state such that a center axis is conformed to a center axis of the small hole.

The shaft portion 45 is inserted to the small hole and the spring along the center axis of the spring. Therefore, the elastic member 43 is penetrated by the shaft portion 45.

The swelling portion 47 has a larger diameter than the spring, and is attached to an upper end of the shaft portion 45 in a state such that the shaft portion 45 passes through the elastic member 43.

In other words, the swelling portion 47 is arranged on the upper end of the lifting pin 27, the swelling portion 47 is inserted to the inside of the tube portion 41, and the lower end of the tube portion 41 is covered with the edge portion 42 in a state such that the elastic member 43 is arranged below the swelling portion 47. The upper end of the elastic member 43 comes into contact with the swelling portion 47, and the lower end of the elastic member 43 comes into contact with the edge portion 42. In other words, the lifting pin 27 and the lid member 26 are connected via the elastic member 43.

Here, the lid member 26 has a buffer member 44.

The buffer member 44 is arranged in a hollow inner portion of the tube portion 41, and is fixed to a contact surface which is the back surface of the lid member; and the lifting pin 27 is structured in a manner such that the swelling portion 47 in the upper end comes into contact with the buffer member 44.

The buffer member 44 is made of a material having an abrasion resistance (e.g., polyether ether ketone (PEEK) resin). The buffer member 44 prevents the contact surface 38 and the upper end of the lifting pin 27 from abrasion.

When the lifting pin 27 is moved down from a state such that the lifting pin 27 is in contact with the buffer member 44, the lifting pin 27 is separated from the buffer member 44.

The elastic member 43 is pinched by the swelling portion 47 and the edge portion 42. When the lifting pin 27 moves down in this state, and a distance between the swelling portion 47 and the edge portion 42 becomes shorter, the elastic member is compressed and presses the edge portion 42 downwardly.

At this time, the lid portion placement surface 36 directed upward in the external surface of the lid member 26 is made so as to be parallel to the table placement surface 35 with each other.

On the other hand, when the lifting pin 27 is moved up from its current state, the upper end of the lifting pin 27 is brought into contact with the back surface of the lid member 26 which is exposed to the inside of the tube portion 41, and the lid member 26 is pressed upward from the lifting pin 27 and moves up.

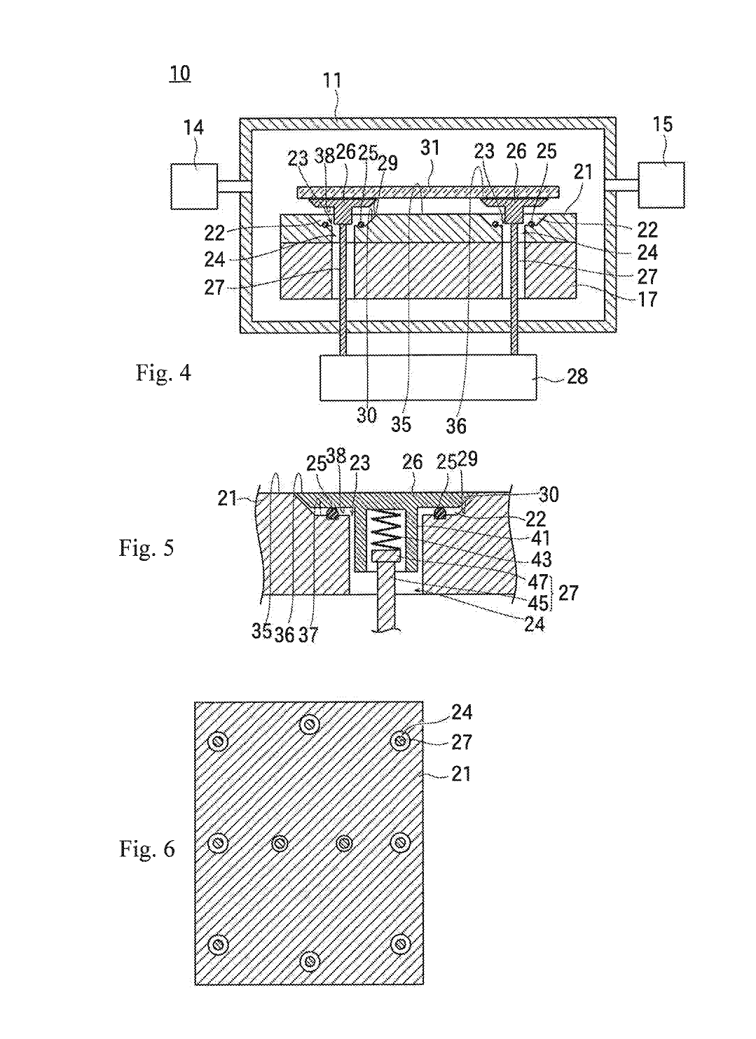

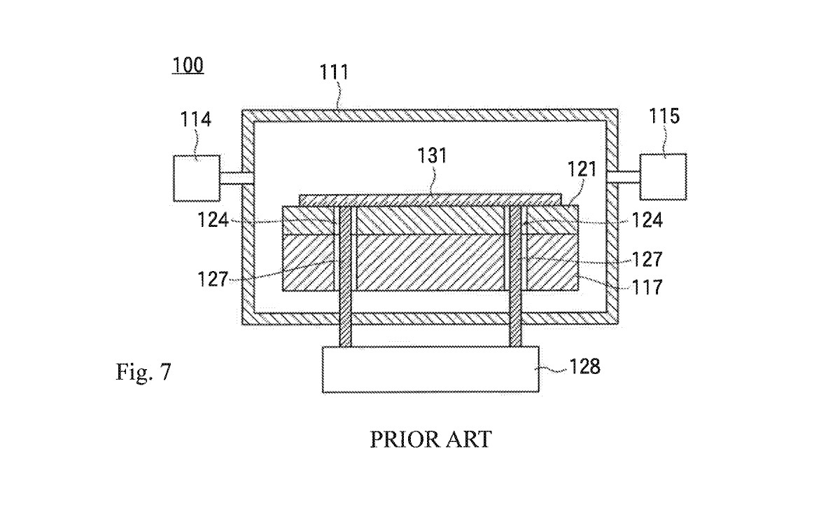

FIG. 4 shows a state such that the lid member 26 moves up and is lifted upward above the table placement surface 35. Even when the lid member 26 is moved upward as discussed above, the lid portion placement surface 36 of the lid member 26 and the table placement surface 35 are made so as to be parallel to each other. The table placement surface 35 is set horizontally; and when the lid member 26 is moved up by the lifting pin 27 while the substrate 31 is arranged on the table placement surface 35, the substrate 31 arranged on the table placement surface 35 is placed on the lid member 26, and is separated from the table placement surface 35 in a horizontal state.

When the lifting pin 27 having moved up is moved down, the lid member 26 is moved down together with the lifting pin 27, the lid member 26 is arranged inside the depression 22, and the substrate 31 placed on the lid member 26 is placed on the table placement surface 35 in contact with the table placement surface 35 of the placement table 21. Such a state is shown in FIG. 1.

In the vacuum treatment device 10 according to the present invention, the annular seal member 25 annularly surrounding the opening 23 is arranged inside the depression 22 of the placement table 21, and the lid member 26 which is arranged inside the depression 22 comes into contact with the seal member 25 by the downward movement of the lifting pin 27. The contact portion is annular and surrounds the opening 23.

At this time, the contact portion between the depression 22 and the seal member 25 is also annular and annularly surrounds the opening 23.

At this time, the surface of the lid member 26 comes into contact with the depression 22 at a position which is above the position of the contact portion between the lid member 26 and the seal member 25, and the position of the contact portion between the inner surface of the depression 22 and the seal member 25.

In the embodiment, the seal member 25 is arranged in the portion of the bottom surface 37 of the depression 22 in the placement table 21, facing the back surface of the lid member 26 in a state of conforming the center axis of the seal member 25 to the center axis of the opening 23 so as to surround the periphery of the opening 23. Here, the material of the seal member 25 is fluorine rubber, but any other compression deformable materials can be used.

When the lifting pin 27 is moved down, the lid member 26 moves down, and the back surface of the lid member 26 comes into contact with the seal member 25, which is in an annular shape. Subsequently, when the lifting pin 27 is further moved down and the lid member 26 is moved down, the back surface including the contact surface 38 of the lid member 26 is pressed against the seal member 25 as shown in FIG. 3, and the seal member 25 is pressed and deformed. Here, the contact surface 38 is pressed against the seal member 25.

The seal member 25 is annularly in close contact with each of the inner surface of the depression 22 including the bottom surface 37 and the side surface 30 of the depression 22 end the back surface of the lid member 26 including the contact surface 38; and thus, the inner space and the outer space of the ring of the seal member 25 are separated. In other words, the internal space of the through hole 24 is separated from the space above the table placement surface 35 in the interior of the vacuum chamber 11.

In the present embodiment of the present invention, the lid member 26 and the lifting pin 27 are connected via the elastic member 43, and when the lifting pin 27 moves down so as to press the seal member 25 from a state where the back surface of the lid member 26 does not press the seal member 25, the elastic member 43 is also pressed and deformed (compressed here). Inside the compression deformed elastic member 43, a restoring force is generated for returning to the original state when the pressing is cancelled. Therefore, even if the downward movement of the lifting pin 27 stops and the pressing of the lifting pin 27 is finished, the seal member 25 maintains the state in which the seal member 25 is pressed by the restoring force of the elastic member 43, as long as the restoring force is generated in the state such that the lifting pin 27 is stopped.

In the case where the lifting pin 27 is moved down in an excessive manner, the elastic member 43 deforms so that there is no risk that the lid member 26 and the placement table 21 are broken due to collision, and it is possible to easily control the output of the lifting device 28.

In the description discussed above, the elastic member 43 is structured such as to be compressed by downward movement of the lifting pin 27. However, when the elastic member 43 is deformed by downward movement of the lifting pin 27 and the lid member 26 is pressed downward by the restoring force, it is possible to structure, as shown in FIG. 5, the elastic member 43 to be arranged between the back surface of the lid member 26 and the upper end of the lifting pin 27, the elastic member 43 to be extended by a downward movement of the lifting pin 27, and the restoring force towing the lid member 26 downward is generated. However, in the structure shown in FIG. 5, when the lifting pin 27 is moved up, the elastic member 43 is compressed, and there is a risk that the vibration is generated in the lid member 26. Accordingly, the structural arrangement as shown in FIG. 2 is preferable.

In the present embodiment, an edge portion which is an opening of the depression 22 exposed to the table placement surface 35 is larger than the bottom surface 37 of the depression 22, and the side surface 30 of the depression 22 is inclined so as to be directed upward.

The lid portion placement surface 36 of the lid member 26 is formed larger than the contact surface 38 which forms a back surface of the lid portion placement surface 36; and the side surface 29 of the lid member 26 is inclined downward.

A shape of the side surface 30 of the depression 22 is a bottomless cylindrical shape, and a shape of the side surface 29 of the lid member 26 is also a bottomless cylindrical shape. When the respective bottomless cylindrical shapes are congruent, the side surface 30 of the depression 22 can be in close contact with the side surface 29 of the lid member 26 when the lid member 26 is arranged inside the depression 22.

In the present embodiment, however, because the seal member 25 is positioned between the contact surface 38 and the bottom surface of the depression 22, the side surface 29 of the lid member 26 can be brought into contact with the side surface 30 of the depression 22 while the contact surface 38 and the bottom surface 37 are in contact with the seal member 25, in a non-contact state of the contact surface 38 and the bottom surface 37 of the depression 22, by deleting the lower end portion of the bottomless cylindrical shape of the side surface 29 of the lid member 26 under the congruent state in a vertical direction at a thickness of the pressed and deformed seal member 25 or more, in the case where the thickness of the pressed and deformed seal member 25 does not come to zero.

Further, in order to securely prevent the contact surface 38 from protruding upward from the table placement surface 35 when the lid member 26 is arranged inside the depression 22 by bringing the side surface 29 of the lid member 26 into contact with the side surface 30 of the depression 22 so as to arrange the lid member 26 inside the depression 22, an upper end portion of the bottomless cylindrical shape of the side surface 29 of the lid member 26 under the congruent state can be deleted in the vertical direction only at a small distance.

When a lower end portion having the bottomless cylindrical shape of the side surface 29 of the lid member 26 is deleted under the state such that the bottomless cylindrical shape thereof is congruent with the bottomless cylindrical shape of the side surface 30 of the depression 22, the back surface of the lid member 26 becomes larger than the bottom surface of the depression 22, and becomes smaller than the edge portion which is the upper end portion of the depression 22.

A thickness of the shaft portion 45 of the lifting pin 27 and a thickness of the swelling portion 47 are formed smaller than a thickness of the through hole 24; and a gap is formed between an inner peripheral side surface of the through hole 24 and an outer peripheral side surface of the lifting pin 27. Therefore, even in the case where a center axis of the through hole 24 does not coincide with a center axis of the lifting pin 27, the shaft portion 45 lifts and moves inside the through hole 24 and the lid member 26 moves downward in a non-contact state with the inner peripheral surface of the through hole 24.

In this case, a part of the side surface 29 of the lid member 26 comes into contact with the side surface 30 of the depression 22 in a state in which the lid portion placement surface 36 is positioned above the table placement surface 35, and the side surface 26 slides down along the side surface 30 of the depression 22 with the further drop of the lifting pin 27, so that the lid member 26 is naturally arranged at a position covering the opening 23.

By downward movement of the lifting pin 27, the back surface of the lid member 26 annularly close contact with the seal member 25, and the side surface 29 of the lid member 26 annularly comes into contact with the side surface 30 of the depression 22 in a state such that the back surface of the lid member 26 is separated from the bottom surface of the depression 22. When the side surface 29 of the lid member 26 annularly comes into contact with the side surface 30 of the depression 22, it is possible to inhibit the gas from flowing through the gap between the side surface 29 of the lid member 26 and the side surface 30 of the depression 22.

In the present embodiment, a heater 17 is arranged in a contact manner on a back surface which is opposite to the table placement surface 35 of the placement table 21, the placement table 21 is heated by heat conduction by the heat generation of the heater 17, and the substrate 31 on the placement table 21 is heated.

The material of the lid member 26 is identical to the material of the placement table 21, and is, for example, aluminum. When the placement table 21 is heated by the heater 17, the lid member 26 and the placement table 21 are heated at the same time so as to generate no difference in a temperature distribution, and the substrate 31 on the placement table 21 is uniformly heated.

### <Method of Using Vacuum Treatment Device>

A description will be given of a vacuum treatment method using the vacuum treatment device 10 discussed above, by exemplifying a method of forming an alumina film by ALD process.

Vacuum ambience is formed by connecting an vacuum evacuation device 15 to the vacuum chamber 11 and evacuating an inside of the vacuum chamber 11 by the vacuum evacuation device 15. The vacuum ambience inside the vacuum chamber 11 is maintained by continuing the vacuum evacuation by the vacuum evacuation device 15.

The lid member 26 is moved up by moving up of the lifting pin 27, and the surface of the lid member 26 is positioned above the table placement surface 35 of the placement table 21.

The substrate 31 is carried in the vacuum chamber 11 while maintaining the vacuum ambience inside the vacuum chamber 11, and the substrate 31 is placed on the lid member 26.

The lid member 26 and the substrate 31 are together moved down by downward movement of the lifting pin 27, and the substrate 31 is brought into contact with the table placement surface 35 of the placement table 21, and is placed on the table placement surface 35.

At this time, the back surface of the lid member 26 comes into contact with the seal member 25, the seal member 25 deforms so as to have an annular close contact with the back surface of the lid member 26, and the space inside the through hole 24 is separated from the space outside the through hole 24.

Furthermore, the back surface of the lid member 26 and the bottom surface of the depression 22 in a state of being separated from each other, the side surface 29 of the lid member 26 annularly come into contact with the side surface 30 of the depression 22.

The heater 17 is heated to, for example, 120° C. The placement table 21 is heated by the thermal conduction from the heater 17; the lid member 26 is heated by the thermal conduction or the thermal radiation from the placement table 21; and the substrate 31 is heated by the thermal conduction or the thermal radiation from the placement table 21 and the lid member 26.

The lid member 26 has the same material as the placement table 21; any temperature difference is not generated between the lid member 26 and the placement table 21; and any uneven heating is not caused in the substrate 31 on the placement table 21.

When the gas discharge device 14 is connected to the vacuum chamber 11, and raw material gas (for example, trimethyl aluminum (TMA) gas) is discharged into the vacuum chamber 11, the discharged raw material gas reaches the heated surface of the substrate 31 so as to be adsorbed, and an atomic layer of the raw material gas is formed on the surface of the substrate 31. The raw material gas, which is not adsorbed to the surface of the substrate 31, is vacuum evacuated to the outside of the vacuum chamber 11 by the vacuum evacuation device 15.

The vacuum ambience is formed inside the vacuum chamber 11 by stopping the supply of the raw material gas after forming the atomic layer of the raw material gas.

Next, when reaction gas (for example, water vapor) reacting with the raw material gas is discharged from the gas discharge device 14, the discharged reaction gas reaches the surface of the heated substrate 31, and reacts with the atomic layer of the raw material gas, and a thin film of reaction product (for example, alumina) is formed on the surface of the substrate 31. The reaction gas which has not reacted and by-product material gas (for example, methane), which is generated by the reaction, are vacuum evacuated to the outside of the vacuum chamber 11 by the vacuum evacuation device 15.

The vacuum ambience is formed inside the vacuum chamber 11 by stopping the supply of the reaction gas after forming the thin film of the reaction product.

In the vacuum treatment device 10 according to the present invention, the side surface 29 of the lid member 26 and the side surface 30 of the depression 22 are annularly brought into contact with each other, the raw material gas or the reaction gas circulating around the gap between the back surface of the substrate 31 and the table placement surface 35 of the placement table 21 is restricted from flowing into the gap between the side surface 29 of the lid member 26 and the side surface 30 of the depression 22. That is, the gas flow change is not generated around the through hole 24 in the table placement surface 35 of the placement table 21. Therefore, the film thickness distribution of the film of the reaction product formed on the substrate 31 becomes uniform.

Further, a part of the gas enters the gap of the contact portion even in the case where the side surface 29 of the lid member 26 annularly comes into contact with the side surface 30 of the depression 22. However, in the vacuum treatment device 10 according to the present invention, the space inside the through hole 24 and the space outside the through hole 24 are separated by the seal member 25, and the gas does not flow into the space inside the through hole 24. Therefore, the reaction product is deposited on the inner peripheral side surface of the through hole 24 so as to form a particle source.

The thin film of the reaction product is laminated on the surface of the substrate 31 by repeating the supply of the raw material gas and the supply of the reaction gas.

The lid member 26 is moved up by moving up of the lifting pin 27 in such a state where the supply of the raw material gas and the reaction gas is stopped after the formation of the film having a desired thickness, the substrate 31 being placed on the lid member 26 and being separated from the table placement surface 35 of the placement table 21. Next, the substrate 31 on the lid member 26 is carried out to the outside of the vacuum chamber 11 while maintaining the vacuum ambience inside the vacuum chamber 11.

The description discussed above is made by exemplifying the ALD process as the vacuum treatment method. However, the vacuum treatment device 10 according to the present invention is not limited to the case where it is used in the ALD process. The vacuum treatment device 10 of the present invention can be applied to other vacuum treatment methods as well (such as, a gas etching process).

In the above example, the depression 22 has the flat bottom surface 37; however, the bottom surface thereof may be curved, and the internal surface of the depression 22 may be constructed by the side surface 30 and the opening 23 in the case where the depression 22 does not have any bottom surface, and has the seal member which can annularly come into contact with the lid member 26 on the internal surface of the depression 22 while surrounding the opening 23.

Furthermore, in the above example, the shape of the side surface 29 of the lid member 26 and the shape of the side surface 30 of the depression 22 are linear when the lid member 26 and the depression 22 are cut in the vertical direction. However, the shapes may be curved or broken curve as long as the side surface 29 of the lid member 26 can come into contact with the side surface 30 of the depression 22.

Moreover, the buffer member 44 is attached to the lid member 26. However, the buffer member 44 may be structured such that the buffer member 44 lifts and moves together with the lifting movement of the shaft member 45, by being fixed onto the swelling portion 47.

In the embodiment discussed above, the seal member 25 is provided inside the depression 22; however, it may be structured so as to be provided in the lid member 26, lift and move together with the lid member 26. However, the seal member 25 can be provided on the lid member 26 in such a manner that the seal member 25 lifts and moves down together with the lid member 26, and the lid member 26 comes into contact with the bottom portion or the side portion of the depression 22 (such as, the bottom surface 37) so as to surround the opening 23 by the contact portion between the lid member 26 and the seal member 25 and the contact portion between the depression 22 and the seal member 25.

### EXPLANATION OF REFERENCE NUMERALS

10 vacuum treatment device
11 vacuum chamber
21 placement table
22 depression
23 opening
24 through hole
25 seal member
26 lid member
27 lifting pin
28 lifting device
31 substrate
35 table placement surface
43 elastic member

What is claimed is:

1. A vacuum treatment device, comprising:
a vacuum chamber;
a placement table which is directed upward and arranged in the vacuum chamber and having a table placement surface where a substrate is placed;
a depression provided in the table placement surface,
wherein the placement table includes a through hole provided in the placement table, the through hole having an opening which is exposed on an internal surface of the depression;
a lifting pin inserted into the through hole and has an upper end connected to a lid member;
a lifting device which lifts and moves the lifting pin,
wherein the lid member is provided on the upper end of the lifting pin and can be lifted and moved between a position inside the depression and a position above the depression by a lifting movement of the lifting pin by the lifting device; and
an annular shaped seal member provided on the internal surface of the depression so as to annularly surround the opening,
wherein the lid member comes down by a downward movement of the lifting pin, and a back surface of the lid member and the internal surface of the depression come into contact with the seal member, whereby the seal member is pressed and deformed, and
wherein the lid member is arranged inside the depression in such a state where the lid member and the seal member are in contact, and a portion where the internal surface of the depression and the seal member are in contact annularly surround the opening.

2. The vacuum treatment device according to claim 1, further comprising an elastic member,
wherein the elastic member is deformed in a case where the seal member is pressed, and the seal member is pressed by a force restoring the deformation of the elastic member.

3. The vacuum treatment device according to claim 1, wherein a back surface of the lid member annularly comes into contact with the internal surface of the depression above a position where the depression and the lid member come into contact with the seal member.

4. The vacuum treatment device according to claim 1, further comprising a bottom surface which is a portion annularly surrounding the opening, in the internal surface of the depression.
wherein the seal member is arranged in the bottom surface, and the seal member comes into contact with the back surface of the lid member.

5. The vacuum treatment device according to claim 1, further comprising a buffer member.
wherein the lid member is moved upward by the lifting pin via the buffer member when the lifting pin moves up.

6. The vacuum treatment device according to claim 2, wherein the elastic member is compressed when-the lifting pin is moved down.

7. The vacuum treatment device according to claim 2, wherein the elastic member is elongated when the lifting pin is moved down.

8. The vacuum treatment device according to claim 1, wherein a side surface of the depression is inclined upward.

9. The vacuum treatment device according to claim 1, wherein a material of the lid member is identical to a material of the placement table.
